(19) United States
(12) Patent Application Publication
(10) Pub. No.: US 2025/0275322 A1
(43) Pub. Date: Aug. 28, 2025

(54) Display Device

(71) Applicant: LG Display Co., Ltd., Seoul (KR)

(72) Inventors: Soojin Kim, Incheon (KR); HeumeIl Baek, Seoul (KR); Dae-Il Kang, Gimpo-si (KR); Sungmoo Kim, Goyang-si (KR)

(21) Appl. No.: 18/925,998

(22) Filed: Oct. 24, 2024

(30) Foreign Application Priority Data
Feb. 26, 2024 (KR) 10-2024-0027404

(51) Int. Cl. H01L 33/62; H01L 25/075; H01L 33/56

(52) U.S. Cl. CPC H10H 20/857; H01L 25/0753; H10H 20/854

(57) ABSTRACT

A display device comprises a substrate on which subpixels comprising a red subpixel, a green subpixel, and a blue subpixel are defined, a red light-emitting element in the red subpixel, green light-emitting elements in the green subpixel and comprising a first green light-emitting element and a second green light-emitting element connected in parallel to the first green light-emitting element, and blue light-emitting elements in the blue subpixel and comprising a first blue light-emitting element and a second blue light-emitting element connected in parallel to the first blue light-emitting element, wherein the red light-emitting element is different in structure from the green light-emitting elements and the blue light-emitting elements and the green light-emitting elements and the blue light-emitting elements are identical in structure. Therefore, the display device has improved the luminous efficiency of each of the subpixels, and thus can provide the high-resolution display device.

### CROSS-REFERENCE TO RELATED APPLICATION

This application claims the priority of Republic of Korea Patent Application No. 10-2024-0027404 filed on Feb. 26, 2024, which is hereby incorporated by reference in its entirety.

### TECHNICAL FIELD

The present specification relates to a display device, and more particularly, to a display device, which uses a light-emitting diode (LED), and a method of manufacturing the same.

### BACKGROUND

As display devices used for a monitor of a computer, a television (TV) set, a mobile phone, and the like, there are an organic light-emitting display (OLED) configured to autonomously emit, and a liquid crystal display (LCD) that requires a separate light source.

The range of application of the display devices is diversified from the monitor of the computer and the TV set to personal mobile devices, and studies are being conducted on the display devices having wide display areas and having reduced volumes and weights.

In addition, recently, a display device including a light-emitting diode (LED) has attracted attention as a next-generation display device. Because the LED is made of an inorganic material instead of an organic material, the LED is more reliable and has a longer lifespan than a liquid crystal display device or an organic light-emitting display device. In addition, the LED can be quickly turned on or off, have excellent luminous efficiency, high impact resistance, and great stability, and display high-brightness images.

### SUMMARY

An object to be achieved by the present specification is to provide a high-resolution display device in which light-emitting elements with different shapes are disposed in each subpixel.

Another object to be achieved by the present specification is to provide a display device in which light-emitting elements with different shapes are disposed in each subpixel, thereby improving luminous efficiency.

Technical problems of the present specification are not limited to the aforementioned technical problems, and other technical problems, which are not mentioned above, can be clearly understood by those skilled in the art from the following descriptions.

According to an aspect of the present specification, the display device comprises a substrate on which a plurality of subpixels comprising a red subpixel, a green subpixel, and a blue subpixel are defined, a red light-emitting element disposed in the red subpixel, a plurality of green light-emitting elements disposed in the green subpixel and comprising a first green light-emitting element and a second green light-emitting element connected in parallel to the first green light-emitting element, and a plurality of blue light-emitting elements disposed in the blue subpixel and comprising a first blue light-emitting element and a second blue light-emitting element connected in parallel to the first blue light-emitting element, wherein the red light-emitting element is different in structure from the plurality of green light-emitting elements and the plurality of blue light-emitting elements and the plurality of green light-emitting elements and the plurality of blue light-emitting elements are identical in structure. Therefore, the display device has improved the luminous efficiency of each of the subpixels, and thus can provide the high-resolution display device.

Other detailed matters of the exemplary embodiments are included in the detailed description and the drawings.

According to the present specification, the light-emitting elements with different structures are disposed in each of the plurality of subpixels, which can maximize the luminous efficiency of the subpixels.

According to the present specification, the light-emitting elements with different sizes are disposed in each of the plurality of subpixels, which can provide the high-resolution display device.

According to the present specification, the plurality of light-emitting elements are disposed in some subpixels, such that even though any one light-emitting element is defective, another light-emitting element can substitute for the function of the defective light-emitting element, which can minimize a deterioration in yield of the display panel caused by a defective pixel.

The effects according to the present specification are not limited to the above-mentioned effects, and more various effects are included in the present specification.

The effects of the present specification are not limited to the aforementioned effects, and other effects, which are not mentioned above, will be apparently understood to a person having ordinary skill in the art from the following description.

The objects to be achieved by the present specification, the means for achieving the objects, and the effects of the present specification described above do not specify essential features of the claims, and, thus, the scope of the claims is not limited to the disclosure of the present specification.

### BRIEF DESCRIPTION OF DRAWINGS

The above and other aspects, features and other advantages of the present specification will be more clearly understood from the following detailed description taken in conjunction with the accompanying drawings, in which:

FIG. 1 is a schematic configuration view of a display device according to an embodiment of the present specification;

FIG. 2A is a partial cross-sectional view of the display device according to the embodiment of the present specification;

FIG. 2B is a perspective view of a tiling display device according to the embodiment of the present specification;

FIG. 3A is a circuit diagram of a red subpixel of the display device according to the embodiment of the present specification;

FIG. 3B is a circuit diagram of a green subpixel of the display device according to the embodiment of the present specification;

FIG. 3C is a circuit diagram of a blue subpixel of the display device according to the embodiment of the present specification;

FIG. 4 is a schematic top plan view of the display device according to the embodiment of the present specification;

FIG. 5 is a cross-sectional view taken along line IV-IV′ in FIG. 4 according to the embodiment of the present specification;

FIG. 6 is a cross-sectional view taken along line V-V′ in FIG. 4 according to the embodiment of the present specification; and

FIG. 7 is a cross-sectional view taken along line VI-VI′ in FIG. 4 according to the embodiment of the present specification.

### DETAILED DESCRIPTION

Advantages and characteristics of the present specification and a method of achieving the advantages and characteristics will be clear by referring to exemplary embodiments described below in detail together with the accompanying drawings. However, the present specification is not limited to the exemplary embodiments disclosed herein but will be implemented in various forms. The exemplary embodiments are provided by way of example only so that those skilled in the art can fully understand the specification of the present specification and the scope of the present specification.

The shapes, sizes, ratios, angles, numbers, and the like illustrated in the accompanying drawings for describing the exemplary embodiments of the present specification are merely examples, and the present specification is not limited thereto. Like reference numerals generally denote like elements throughout the specification. Further, in the following description of the present specification, a detailed explanation of known related technologies can be omitted to avoid unnecessarily obscuring the subject matter of the present specification. The terms such as “including,” “having,” and “comprising” used herein are generally intended to allow other components to be added unless the terms are used with the term “only”. Any references to singular can include plural unless expressly stated otherwise.

Components are interpreted to include an ordinary error range even if not expressly stated.

When the position relation between two parts is described using the terms such as “on”, “above”, “below”, and “next”, one or more parts can be positioned between the two parts unless the terms are used with the term “immediately” or “directly”.

When an element or layer is disposed “on” another element or layer, another layer or another element can be interposed directly on the other element or therebetween.

Although the terms “first”, “second”, and the like are used for describing various components, these components are not confined by these terms. These terms are merely used for distinguishing one component from the other components. Therefore, a first component to be mentioned below can be a second component in a technical concept of the present

Like reference numerals generally denote like elements throughout the specification.

A size and a thickness of each component illustrated in the drawing are illustrated for convenience of description, and the present specification is not limited to the size and the thickness of the component illustrated.

The features of various embodiments of the present specification can be partially or entirely adhered to or combined with each other and can be interlocked and operated in technically various ways, and the embodiments can be carried out independently of or in association with each other.

Hereinafter, a display device according to exemplary embodiments of the present specification will be described in detail with reference to accompanying drawings.

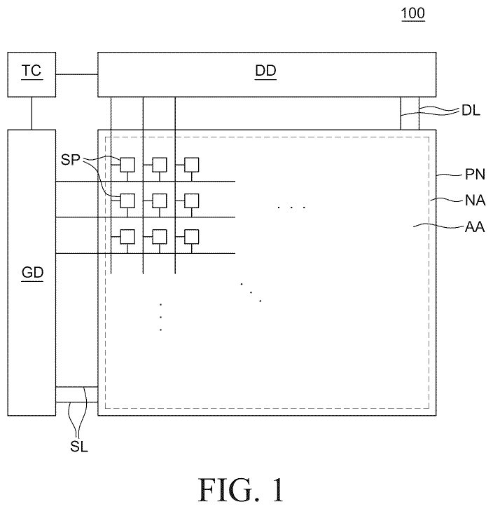

FIG. 1 is a schematic configuration view of a display device according to an embodiment of the present specification. For convenience of description, FIG. 1 illustrates a display panel PN, a gate driver GD, a data driver DD, and a timing controller TC among various constituent elements of a display device 100.

With reference to FIG. 1, the display device 100 includes the display panel PN including the plurality of subpixels SP, the gate driver GD configured to supply various types of signals to the display panel PN, the data driver DD configured to supply various data voltages to the display panel PN, and the timing controller TC configured to control the gate driver GD, and the data driver DD.

The gate driver GD supplies a plurality of scan signals to a plurality of scan lines SL in response to a plurality of gate control signals provided from the timing controller TC. FIG. 1 illustrates that the single gate driver GD is disposed to be spaced apart from one side of the display panel PN. However, the number and arrangement of the gate driver GD are not limited thereto.

The data driver DD supplies data voltages to a plurality of data lines DL in response to a plurality of data control signals and image data provided from the timing controller TC. The data driver DD can convert image data into data voltages by using a reference gamma voltage and supply the converted data voltages to the plurality of data lines DL.

The timing controller TC aligns image data, which are inputted from the outside, and supplies the image data to the data driver DD. The timing controller TC can generate the gate control signals and the data control signals by using synchronizing signals, i.e., dot clock signals, data enable signals, and horizontal/vertical synchronizing signals inputted from the outside. Further, the timing controller TC can control the gate driver GD and the data driver DD by supplying the generated gate control signals and data control signals to the gate driver GD and the data driver DD.

The display panel PN is configured to display images to a user and includes the plurality of subpixels SP. In the display panel PN, the plurality of scan lines SL and the plurality of data lines DL can intersect one another, and the plurality of subpixels SP can be formed at intersection points between the scan line SL and the data line DL.

A display area AA and a non-display area NA can be defined on the display panel PN.

The display area AA is an area of the display device 100 in which images are displayed. The display area AA can include the plurality of subpixels SP constituting a plurality of pixels PX, and a pixel circuit configured to operate the plurality of subpixels SP. The plurality of subpixels SP are minimum units that constitute the display area AA. The n subpixels SP can constitute a single pixel PX. Thin-film transistors and the like for operating a plurality of light-emitting elements R_LED, G_LED, and B_LED can be disposed in each of the plurality of subpixels SP. The plurality of light emitting elements R_LED, G_LED, and B_LED can be differently defined depending on the type of display panel PN. For example, in case that the display panel PN is an inorganic light-emitting display panel PN, the light-emitting elements R_LED, G_LED, and B_LED can each be a light-emitting diode (LED) or a micro light-emitting diode (micro-LED).

A plurality of signal lines for transmitting various types of signals to the plurality of subpixels SP are disposed in the display area AA. For example, the plurality of signal lines can include the plurality of data lines DL for supplying data voltages to the plurality of subpixels SP, and the plurality of scan lines SL for supplying scan signals to the plurality of subpixels SP. The plurality of scan lines SL can extend in one direction in the display area AA and be connected to the plurality of subpixels SP. The plurality of data lines DL can extend in a direction different from one direction in the display area AA and be connected to the plurality of subpixels SP. In addition, a low-potential power line EVSS, a high-potential power line EVDD, and the like can be further disposed in the display area AA. However, the present specification is not limited thereto.

The non-display area NA can be defined as an area in which no image is displayed, i.e., an area extending from the display area AA. The non-display area NA can include link lines and pad electrodes for transmitting signals to the subpixels SP in the display area AA. Alternatively, the non-display area NA can include drive ICs such as gate driver ICs and data driver ICs.

Meanwhile, the non-display area NA can be positioned on a rear surface of the display panel PN, i.e., a surface on which the subpixel SP is not present. Alternatively, the non-display area NA can be excluded. However, the present specification is not limited to the configuration illustrated in the drawings.

Meanwhile, the drivers such as the gate driver GD, the data driver DD, and the timing controller TC can be connected to the display panel PN in various ways. For example, the gate driver GD can be mounted in the non-display area NA by a gate-in-panel (GIP) method or mounted between the plurality of subpixels SP by a gate-in-active area (GIA) method in the display area AA.

For example, the data driver DD and the timing controller TC can be formed on a separate flexible film and a printed circuit board and electrically connect the display panel PN, the data driver DD, and the timing controller TC by a method of bonding the flexible film and the printed circuit board to a pad electrode formed in the non-display area NA of the display panel PN.

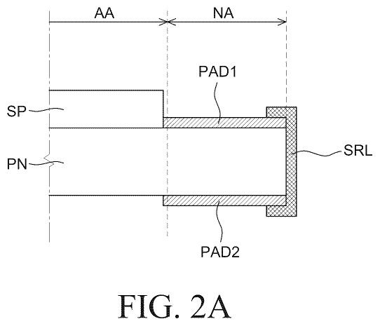

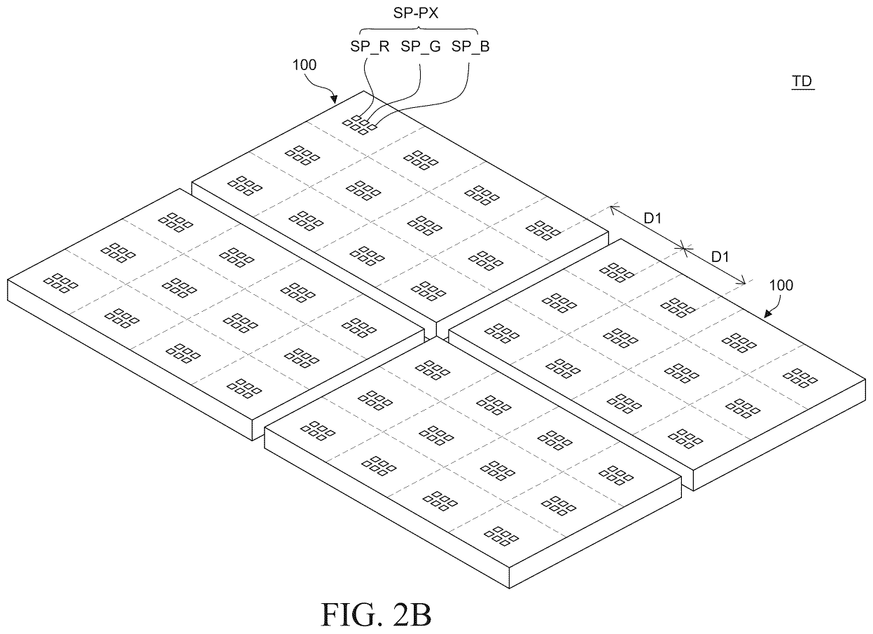

As another example, in case that the gate driver GD is mounted in the display area AA by the GIA method and a side line SRL, which connects a signal line on a front surface of the display panel PN to the pad electrode on the rear surface of the display panel PN, is formed to bond the flexible film and the printed circuit board to the rear surface of the display panel PN, it is possible to minimize the non-display area NA on the front surface of the display panel PN. Therefore, in case that the gate driver GD, the data driver DD, and the timing controller TC are connected to the display panel PN by the above-mentioned method, a zero bezel in which the bezel is not substantially present can be implemented. A more detailed description will be described with reference to FIGS. 2A and 2B.

FIG. 2A is a partial cross-sectional view of the display device according to the embodiment of the present specification. FIG. 2B is a perspective view of a tiling display device according to the embodiment of the present specification.

A plurality of pad electrodes for transmitting various types of signals to the plurality of subpixels SP are disposed in the non-display area NA of the display panel PN. For example, a first pad electrode PAD1 configured to transmit signals to the plurality of subpixels SP is disposed in the non-display area NA on the front surface of the display panel PN. A second pad electrode PAD2 electrically connected to drive components such as the flexible film and the printed circuit board is disposed in the non-display area NA on the rear surface of the display panel PN.

In this case, although not illustrated in the drawings, various types of signal lines, e.g., the scan line SL, the data line DL, or the like connected to the plurality of subpixels SP can extend from the display area AA to the non-display area NA and be electrically connected to the first pad electrode PAD1.

Further, the side line SRL is disposed along a side surface of the display panel PN. The side line SRL can electrically connect the first pad electrode PAD1 on the front surface of the display panel PN and the second pad electrode PAD2 on the rear surface of the display panel PN. Therefore, the signals received from the drive components on the rear surface of the display panel PN can be transmitted to the plurality of subpixels SP through the second pad electrode PAD2, the side line SRL, and the first pad electrode PAD1. Therefore, a signal transmission route is defined from the front surface to the side surface and the rear surface of the display panel PN, which can minimize an area of the non-display area NA of the front surface of the display panel PN.

Further, with reference to FIG. 2B, a tiling display device TD having a large screen can be implemented by connecting a plurality of display devices 100. In this case, as illustrated in FIG. 2A, in case that the tiling display device TD is implemented by using the display device 100 with the minimized bezel, a seam area in which no image is displayed between the display devices 100 can be minimized or at least reduced, thereby improving display quality.

For example, the plurality of subpixels SP can constitute a single pixel PX. An interval D1 between an outermost peripheral pixel PX of one display device 100 and an outermost peripheral pixel PX of another display device 100 adjacent to one display device 100 can be implemented to be equal to the interval D1 between the pixels PX in one display device 100. Therefore, the seam area can be minimized or at least reduced as a constant interval of the pixels PX is implemented between the display device 100 and the display device 100.

However, as illustrated in FIG. 2A and FIG. 2B, the display device 100 according to the embodiment of the present specification can be a general display device in which the bezel is present. However, the present specification is not limited thereto.

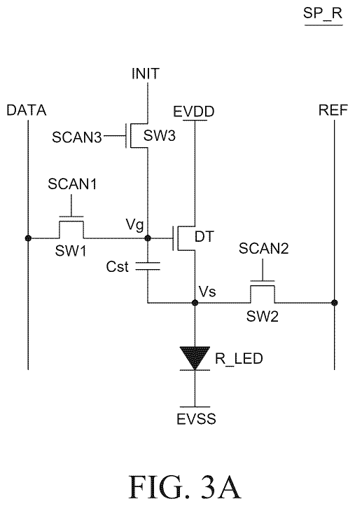

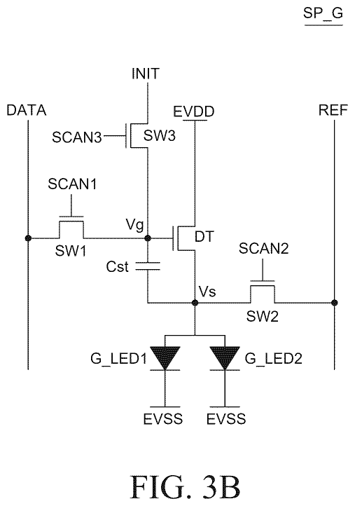

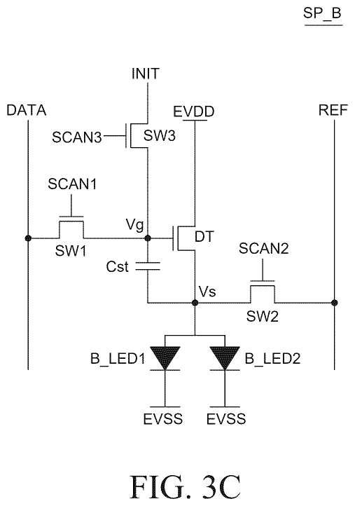

FIG. 3A is a circuit diagram of a red subpixel of the display device according to the embodiment of the present specification.

A red subpixel SP_R of the display device 100 according to the embodiment of the present specification has a red light-emitting element R_LED, and a pixel circuit configured to operate the red light-emitting element R_LED.

In this case, the pixel circuit can include first to third switching transistors SW1, SW2, and SW3, a storage capacitor Cst, and a driving transistor DT.

A first switching transistor SW1 charges the storage capacitor Cst with a data voltage DATA in response to a first scan signal SCAN1.

The driving transistor DT adjusts the amount of light emission of the red light-emitting element R_LED by controlling the amount of electric current to be supplied to the red light-emitting element R_LED on the basis of the data voltage with which the storage capacitor Cst is charged.

A second switching transistor SW2 initializes the driving transistor DT and the storage capacitor Cst to a reference voltage REF in response to a second scan signal SCAN2.

A third switching transistor SW3 senses and compensate for a threshold voltage of the driving transistor DT while initializing the driving transistor DT and the storage capacitor Cst, together with the second switching transistor SW2, to an initialization voltage INIT in response to a third scan signal SCAN3.

The storage capacitor Cst can be electrically connected between a gate electrode GE and a source electrode SE of the driving transistor DT and maintain the data voltage DATA, which corresponds to an image signal voltage, or a voltage, which corresponds to the data voltage DATA, for one frame time.

FIG. 3B is a circuit diagram of a green subpixel of the display device according to the embodiment of the present specification, and FIG. 3C is a circuit diagram of a blue subpixel of the display device according to the embodiment of the present specification. Subpixels SP_G and SP_B in FIGS. 3B and 3C are substantially identical in configuration to the red subpixel SP_R in FIG. 3A, except for light-emitting elements G_LED and B_LED. Therefore, repeated descriptions of the identical components will be omitted.

With reference to FIGS. 3B and 3C, in the green subpixel SP_G and the blue subpixel SP_B of the display device 100 according to the embodiment of the present specification, first light-emitting elements G_LED1 and B_LED1 and second light-emitting elements G_LED2 and B_LED2 are respectively connected in parallel.

Therefore, even though any one light-emitting element is defective among the first light-emitting elements G_LED1 and B_LED1 and the second light-emitting elements G_LED2 and B_LED2, the electric current is supplied to another light-emitting element that is not defective, such that the light-emitting element, which is not defective, can substitute for the function of the defective light-emitting element.

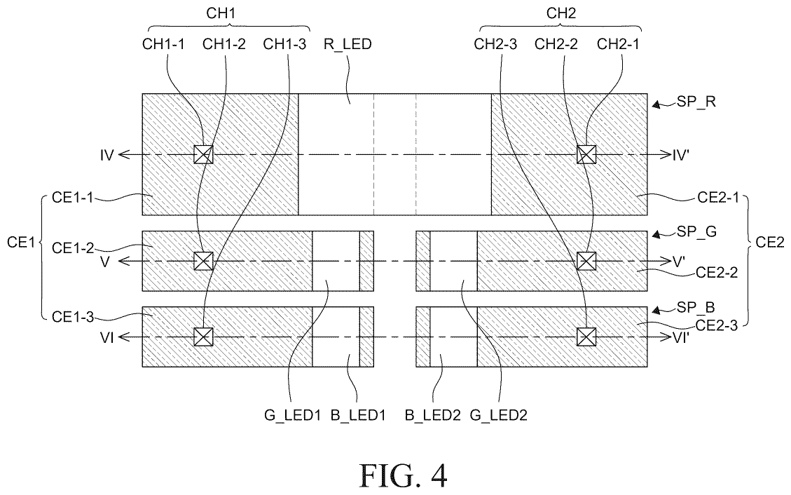

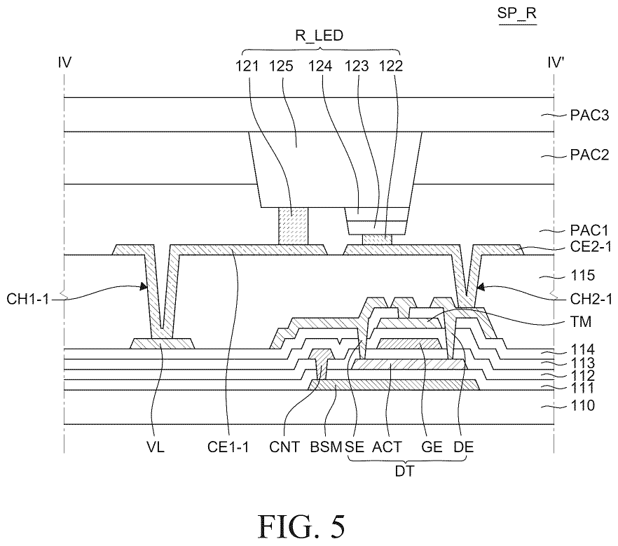

FIG. 4 is a schematic top plan view of the display device according to the embodiment of the present specification. For convenience of description, FIG. 4 illustrates a plurality of first connection electrodes CE1, a plurality of second connection electrodes CE2, a plurality of first contact holes CH1, a plurality of second contact holes CH2, the red light-emitting element R_LED, the first and second green light-emitting elements G_LED1 and G_LED2, and the first and second blue light-emitting elements B_LED1 and B_LED2. In addition, the planar feature of the subpixel SP will be described with reference to FIG. 4. The components will be specifically described with reference to FIGS. 5 to 7 to be described below.

With reference to FIG. 4, the display device 100 according to the embodiment of the present specification includes the plurality of subpixels SP including a red subpixel SP_R, a green subpixel SP_G, and a blue subpixel SP_B.

A first-first connection electrode CE1-1, which is disposed in a first-first contact hole CH1-1, and a second-first connection electrode CE2-1, which is disposed in a second-first contact hole CH2-1, can be disposed in the red subpixel SP_R. In this case, the first-first connection electrode CE1-1 and the second-first connection electrode CE2-1 can be spaced apart from each other. The red light-emitting element R_LED can be disposed on the first-first connection electrode CE1-1 and the second-first connection electrode CE2-1 and overlap at least a part of the first-first connection electrode CE1-1 and at least a part of the second-first connection electrode CE2-1. That is, the red light-emitting element R_LED can be disposed to cover both one side portion of the first-first connection electrode CE1-1 and one side portion of the second-first connection electrode CE2-1. In this case, the red light-emitting element R_LED does not overlap the first-first contact hole CH1-1 and the second-first contact hole CH2-1.

A first-second connection electrode CE1-2, which is disposed in a first-second contact hole CH1-2, and a second-second connection electrode CE2-2, which is disposed in a second-second contact hole CH2-2, can be disposed in the green subpixel SP_G. In this case, the first-second connection electrode CE1-2 and the second-second connection electrode CE2-2 can be spaced apart from each other. The first green light-emitting element G_LED1 can be disposed on one side portion of the first-second connection electrode CE1-2. In addition, the other side portion of the first-second connection electrode CE1-2 can be disposed in the first-second contact hole CH1-2. Likewise, the second green light-emitting element G_LED2 can be disposed on one side portion of the second-second connection electrode CE2-2. In addition, the other side portion of the second-second connection electrode CE2-2 can be disposed in the second-second contact hole CH2-2. In this case, the first green light-emitting element G_LED1 and the first-second contact hole CH1-2 do not overlap each other. In addition, the second green light-emitting element G_LED2 and the second-second contact hole CH2-2 do not overlap each other.

A first-third connection electrode CE1-3, which is disposed in a first-third contact hole CH1-3, and a second-third connection electrode CE2-3, which is disposed in a second-third contact hole CH2-3, can be disposed in the blue subpixel SP_B. In this case, the first-third connection electrode CE1-3 and the second-third connection electrode CE2-3 can be spaced apart from each other. A first blue light-emitting element B_LED1 can be disposed on one side portion of the first-third connection electrode CE1-3. In addition, the other side portion of the first-third connection electrode CE1-3 can be disposed in the first-third contact hole CH1-3. Likewise, the second blue light-emitting element B_LED2 can be disposed on one side portion of the second-third connection electrode CE2-3. In addition, the other side portion of the second-third connection electrode CE2-3 can be disposed in the second-third contact hole CH2-3. In this case, the first blue light-emitting element B_LED1 and the first-third contact hole CH1-3 do not overlap each other. In addition, the second blue light-emitting element B_LED2 and the second-third contact hole CH2-3 do not overlap each other.

With reference to FIG. 4, a planar area of the red light-emitting element R_LED can be larger than a planar area of the first green light-emitting element G_LED1, a planar area of the second green light-emitting element G_LED2, a planar area of the first blue light-emitting element B_LED1, and a planar area of the second blue light-emitting element B_LED2. As described below, the red light-emitting element R_LED can be a flip-chip type light-emitting element, and the first green light-emitting element G_LED1, the second green light-emitting element G_LED2, the first blue light-emitting element B_LED1, and the second blue light-emitting element B_LED2 are vertical type light-emitting elements, such that the red light-emitting element R_LED can have the largest planar area.

The first-first connection electrode CE1-1 can have a larger planar area than the first-second connection electrode CE1-2 and the first-third connection electrode CE1-3. In addition, the second-first connection electrode CE2-1 can have a larger planar area than the second-second connection electrode CE2-2 and the second-third connection electrode CE2-3. As described above, because the planar area of the red light-emitting element R_LED is larger than the planar area of the first green light-emitting element G_LED1, the planar area of the second green light-emitting element G_LED2, the planar area of the first blue light-emitting element B_LED1, and the planar area of the second blue light-emitting element B_LED2, a planar area of each of the first-first connection electrode CE1-1 and the second-first connection electrode CE2-1 connected to the red light-emitting element R_LED can be larger than a planar area of each of the first-second connection electrode CE1-2, the second-second connection electrode CE2-2, a first-third connection electrode CE1-3, and a second-third connection electrode CE2-3 connected to the first green light-emitting element G_LED1, the second green light-emitting element G_LED2, the first blue light-emitting element B_LED1, and the second blue light-emitting element B_LED2.

Therefore, a planar area of each of the green subpixel SP_G and the blue subpixel SP_B can be smaller than a planar area of the red subpixel SP_R. Specifically, because the planar area of each of the first green light-emitting element G_LED1, the second green light-emitting element G_LED2, the first-second connection electrode CE1-2, and the second-second connection electrode CE2-2 included in the green subpixel SP_G is smaller than the planar area of each of the red light-emitting element R_LED, the first-first connection electrode CE1-1, and the second-first connection electrode CE2-1 included in the red subpixel SP_R, a planar area of the green subpixel SP_G can also be smaller than a planar area of the red subpixel SP_R. Likewise, because the planar area of each of the first blue light-emitting element B_LED1, the second blue light-emitting element B_LED2, the first-third connection electrode CE1-3, and the second-third connection electrode CE2-3 included in the blue subpixel SP_B can be smaller than the planar area of each of the red light-emitting element R_LED, the first-first connection electrode CE1-1, and the second-first connection electrode CE2-1 included in the red subpixel SP_R, a planar area of the blue subpixel SP_B can be smaller than a planar area of the red subpixel SP_R. Even though the planar area of each of the green subpixel SP_G and the blue subpixel SP_B is smaller than the planar area of the red subpixel SP_R as described above, the green subpixel SP_G and the blue subpixel SP_B can each include the light-emitting elements G_LED1, G_LED2, B_LED1, and B_LED2 larger in number than the light-emitting elements of the red subpixel SP_R.

Hereinafter, the subpixels SP_R, SP_G, and SP_B according to the embodiment of the present specification will be more specifically described with reference to FIGS. 5 to 7.

FIG. 5 is a cross-sectional view of the red subpixel among the subpixels of the display device taken along line IV-IV′ in FIG. 4 according to the embodiment of the present

With reference to FIG. 5, a substrate 110 can be a substrate, i.e., an insulation substrate that supports constituent elements disposed above the substrate 110. For example, the substrate 110 can be made of glass, resin, or the like. In addition, the substrate 110 can include polymer or plastic. In several embodiments, the substrate 110 can be made of a plastic material having flexibility. The plurality of pixels can be formed on the substrate 110 so that images can be displayed.

A light-blocking layer BSM can be disposed on the substrate 110. The light-blocking layer BSM can block light entering active layers ACT of the plurality of transistors, thereby minimizing a leakage current. For example, the light-blocking layer BSM can be disposed below the active layer ACT of the driving transistor DT and block light entering the active layer ACT. If the light is emitted to the active layer ACT, a leakage current occurs, which can degrade the reliability of the transistor. Therefore, the light-blocking layer BSM for blocking light can be disposed on the substrate 110, thereby improving the reliability of the driving transistor DT. The light-blocking layer BSM can be made of an opaque electrically conductive material, for example, copper (Cu), aluminum (Al), molybdenum (Mo), nickel (Ni), titanium (Ti), chromium (Cr), or an alloy thereof. However, the present specification is not limited thereto.

A buffer layer 111 can be disposed on the light-blocking layer BSM. The buffer layer 111 can reduce the penetration of moisture or impurities through the substrate 110. For example, the buffer layer 111 can be configured as a single layer or multilayer made of silicon oxide (SiOx) or silicon nitride (SiNx). However, the present specification is not limited thereto. However, the buffer layer 111 can be excluded in accordance with the type of substrate 110 or the type of transistor. However, the present specification is not limited thereto.

The driving transistor DT including the active layer ACT, the gate electrode GE, the source electrode SE, and a drain electrode DE can be disposed on the buffer layer 111.

Meanwhile, although not illustrated in FIG. 5, an additional buffer layer can be disposed between the substrate 110 and the light-blocking layer BSM. For example, like the buffer layer 111, the additional buffer layer can be configured as a single layer or multilayer made of silicon oxide (SiOx) or silicon nitride (SiNx) in order to reduce the penetration of moisture or impurities through the substrate 110. However, the present specification is not limited thereto.

First, the active layer ACT of the driving transistor DT can be disposed on the buffer layer 111. The active layer ACT can be made of a semiconductor material such as an oxide semiconductor, amorphous silicon, or polysilicon. However, the present specification is not limited thereto. In addition, although not illustrated in the drawings, in addition to the driving transistor DT, other transistors, such as a switching transistor, a sensing transistor, and a light emission control transistor, can be additionally disposed. The active layers of these transistors can be made of a semiconductor material such as an oxide semiconductor, amorphous silicon, or polysilicon. However, the present specification is not limited thereto. In addition, the active layers of the transistors, such as the driving transistor DT, the switching transistor, the sensing transistor, and the light emission control transistor, which are included in the pixel circuits, can be made of the same material or different materials.

A gate insulation layer 112 can be disposed on the active layer ACT. The gate insulation layer 112 can be an insulation layer for electrically insulating the active layer ACT and the gate electrode GE. The gate insulation layer 112 can be configured as a single layer or multilayer made of silicon oxide (SiOx) or silicon nitride (SiNx). However, the present specification is not limited thereto.

The gate electrode GE can be disposed on the gate insulation layer 112. The gate electrode GE can be made of an electrically conductive material, for example, copper (Cu), aluminum (Al), molybdenum (Mo), nickel (Ni), titanium (Ti), chromium (Cr), or an alloy thereof. However, the present specification is not limited thereto.

In addition, an intermediate electrode CNT can be disposed on the gate insulation layer 112. The intermediate electrode CNT can be made of the same material as the gate electrode GE and electrically connected to the light-blocking layer BSM.

A first interlayer insulation layer 113 can be disposed on the gate electrode GE. Contact holes, through which the source electrode SE and the drain electrode DE are connected to the active layer ACT, can be formed in the first interlayer insulation layer 113. The first interlayer insulation layer 113 can be an insulation layer for protecting components disposed below the first interlayer insulation layer 113. The first interlayer insulation layer 113 can be configured as a single layer or multilayer made of silicon oxide (SiOx) or silicon nitride (SiNx). However, the present specification is not limited thereto.

A conductive layer TM can be disposed on the first interlayer insulation layer 113. The conductive layer TM can be disposed on the gate electrode GE. The conductive layer TM, together with the gate electrode GE, can constitute the storage capacitor Cst. However, the conductive layer TM can be excluded in accordance with the embodiment.

A second interlayer insulation layer 114 can be disposed on the conductive layer TM. Contact holes, through which the source electrode SE and the drain electrode DE are connected to the active layer ACT, can be formed in the second interlayer insulation layer 114. The second interlayer insulation layer 114 can be an insulation layer for protecting components disposed below the second interlayer insulation layer 114. The second interlayer insulation layer 114 can be configured as a single layer or multilayer made of silicon oxide (SiOx) or silicon nitride (SiNx). However, the present specification is not limited thereto.

The source electrode SE and the drain electrode DE, which are electrically connected to the active layer ACT, can be disposed on the second interlayer insulation layer 114. The drain electrode DE is electrically connected to the storage capacitor Cst and a second electrode 122 of the red light-emitting element R_LED, and the source electrode SE is connected to another component of the pixel circuit. The source electrode SE and the drain electrode DE can each be made of an electrically conductive material, for example, copper (Cu), aluminum (Al), molybdenum (Mo), nickel (Ni), titanium (Ti), chromium (Cr), or an alloy thereof. However, the present specification is not limited thereto.

A power line VL can be disposed on the second interlayer insulation layer 114. Specifically, like the source electrode SE and the drain electrode DE, the power line VL is disposed on the second interlayer insulation layer 114 and spaced apart from the source electrode SE and the drain electrode DE, and the power line VL can be made of a material identical to the material of the source electrode SE and the material of the drain electrode DE. However, the present specification is not limited thereto. The power line VL can be a low-potential power line. In this case, a low-potential voltage can be supplied to the power line VL. However, the present specification is not limited thereto. The power line VL can be a high-potential power line.

The power line VL can be connected to the first-first connection electrode CE1-1. The power line VL can be connected to a first electrode 121 of the red light-emitting element R_LED through the first-first connection electrode CE1-1. Therefore, the power line VL can transmit the high-potential voltage or low-potential voltage to the first-first connection electrode CE1-1 and the first electrode 121 of the red light-emitting element R_LED.

An overcoating layer 115 can be disposed on the source electrode SE, the drain electrode DE, and the power line VL. The overcoating layer 115 can be disposed to cover the source electrode SE, the drain electrode DE, and the power line VL. Therefore, the overcoating layer 115 can planarize top surfaces of the components, such as the source electrode SE, the drain electrode DE, and the power line VL, disposed below the overcoating layer 115. In addition, the overcoating layer 115 can include one or more contact holes CH1 and CH2. For example, the overcoating layer 115 can be made of benzocyclobutene or an acrylic-based organic material, for example. However, the present specification is not limited thereto.

The first-first connection electrode CE1-1 and the second-first connection electrode CE2-1 can be disposed on the overcoating layer 115. The first-first connection electrode CE1-1 can be connected to the power line VL. Specifically, the first-first connection electrode CE1-1 can be connected to the power line VL through the first-first contact hole CH1-1 formed in the overcoating layer 115. The second-first connection electrode CE2-1 can be connected to the drain electrode DE of the driving transistor DT through the second-first contact hole CH2-1 formed in the overcoating layer 115.

Meanwhile, the first-first connection electrode CE1-1 and the second-first connection electrode CE2-1 can also serve as reflective plates. The first-first connection electrode CE1-1 and the second-first connection electrode CE2-1 can be disposed below the red light-emitting element R_LED and reflect the light, which is emitted from the red light-emitting element R_LED, toward the upper portion of the substrate 110. Therefore, the first-first connection electrode CE1-1 and the second-first connection electrode CE2-1 can include various conductive layers in consideration of light reflection efficiency and resistance. For example, the first-first connection electrode CE1-1 and the second-first connection electrode CE2-1 can each be made by using an opaque conductive layer, which is made of silver (Ag), aluminum (Al), molybdenum (Mo), titanium (Ti), or an alloy thereof, together with a transparent conductive layer made of indium tin oxide (ITO). However, the present specification is not limited thereto.

The plurality of red light-emitting elements R_LED can be disposed on the first-first connection electrode CE1-1 and the second-first connection electrode CE2-1. According to the embodiment of the present specification, the red light-emitting element R_LED can be a flip-chip type light-emitting element in which the first electrode 121 and the second electrode 122, which will be described below, are disposed on the same plane below the light-emitting element. In the embodiment in FIG. 5, the red light-emitting element R_LED is a flip-chip type light-emitting element with a simpler structure. However, the present specification is not limited thereto. The red light-emitting element R_LED can be a lateral type light-emitting element. Specifically, the first electrode 121 of the red light-emitting element R_LED can be disposed to face the first-first connection electrode CE1-1, and the second electrode 122 can be disposed to face the second-first connection electrode CE2-1.

Although not illustrated in the drawings, a bonding layer can be further disposed between the first-first connection electrode CE1-1 and the first electrode 121 and between the second-first connection electrode CE2-1 and the second electrode 122. In this case, the bonding layer can fix the red light-emitting element R_LED onto the first-first connection electrode CE1-1 and the second-first connection electrode CE2-1. The bonding layer can include an electrically conductive material to electrically connect the first-first connection electrode CE1-1 and the first electrode 121 and electrically connect the second-first connection electrode CE2-1 and the second electrode 122. However, the present specification is not limited thereto. The bonding layer can be excluded in accordance with the embodiment.

The red light-emitting element R_LED includes the first electrode 121, a first semiconductor layer 125, the second electrode 122, a second semiconductor layer 123, and a light-emitting layer 124.

The first electrode 121 of the red light-emitting element R_LED can be electrically connected to the power line VL through the first-first connection electrode CE1-1. Therefore, the first electrode 121 can transmit the voltage, which is transmitted through the power line VL, to the first semiconductor layer 125. For example, the first electrode 121 can be an N-type electrode disposed to inject electrons into the light-emitting layer 124 through the first semiconductor layer 125. The first electrode 121 can be made of an electrically conductive material, for example, a transparent conductive material such as indium tin oxide (ITO) or indium zinc oxide (IZO) or an opaque conductive material such as titanium (Ti), gold (Au), silver (Ag), copper (Cu), or an alloy thereof. However, the present specification is not limited thereto.

The second electrode 122 can be electrically connected to the drain electrode DE of the driving transistor DT through the second-first connection electrode CE2-1. Therefore, the second electrode 122 can transmit a voltage, which is transmitted from the drain electrode DE, to the second semiconductor layer 123. For example, the second electrode 122 can be a P-type electrode for injecting positive holes into the light-emitting layer 124 through the second semiconductor layer 123. The second electrode 122 can be made of an electrically conductive material, for example, a transparent conductive material such as indium tin oxide (ITO) or indium zinc oxide (IZO) or an opaque conductive material such as titanium (Ti), gold (Au), silver (Ag), copper (Cu), or an alloy thereof. However, the present specification is not limited thereto.

The first semiconductor layer 125 can be disposed on the first electrode 121, and the second semiconductor layer 123 can be disposed on the second electrode 122. The first semiconductor layer 125 and the second semiconductor layer 123 can each be a layer formed by injecting N-type or P-type impurities into a material such as indium aluminum phosphide (InAlP) or gallium arsenide (GaAs). For example, the first semiconductor layer 125 can be an N-type semiconductor layer formed by injecting N-type impurities into gallium arsenide (GaAs), and the second semiconductor layer 123 can be a P-type semiconductor layer formed by injecting P-type impurities into gallium arsenide (GaAs). However, the present specification is not limited thereto. In this case, the N-type impurity can be silicon (Si), germanium (GE), tin (Sn), or the like. The P-type impurity can be magnesium (Mg), zinc (Zn), beryllium (Be), or the like. However, the present specification is not limited thereto.

The light-emitting layer 124 can be disposed between the first semiconductor layer 125 and the second semiconductor layer 123. The light-emitting layer 124 can emit light by receiving positive holes and electrons from the first semiconductor layer 125 and the second semiconductor layer 123. The light-emitting layer 124 can be configured as a single layer or a multi-quantum well (MQW) structure.

The red light-emitting element R_LED can be larger in size than a green light-emitting element G_LED and a blue light-emitting element B_LED that will be described below. In this case, the size can be interpreted as a concept including all a planar size, a cross-sectional width, and a volume of the light-emitting element.

Next, a first planarization layer PAC1 can be disposed to surround the plurality of red light-emitting elements R_LED. The first planarization layer PAC1 can overlap top surfaces and side surfaces of the plurality of red light-emitting elements R_LED and fix and protect the plurality of red light-emitting elements R_LED. For example, the first planarization layer PAC1 can be made of benzocyclobutene or an acrylic-based organic material, for example. However, the present specification is not limited thereto.

A second planarization layer PAC2 can be disposed on the first planarization layer PAC1. The second planarization layer PAC2 can be disposed to surround the red light-emitting element R_LED and disposed to expose the top surface of the red light-emitting element R_LED. In this case, a top surface of the second planarization layer PAC2 can be consistent with the top surface of the red light-emitting element R_LED. For example, the second planarization layer PAC2 can be made of benzocyclobutene or an acrylic-based organic material, for example. However, the present specification is not limited thereto.

A third planarization layer PAC3 can be disposed on the second planarization layer PAC2. The third planarization layer PAC3 can completely cover the top surface of the red light-emitting element R_LED, thereby protecting the red light-emitting element R_LED. The third planarization layer PAC3 can be configured as a single layer or multilayer. For example, the third planarization layer PAC3 can be made of benzocyclobutene or an acrylic-based organic material, for example. However, the present specification is not limited thereto.

As described above, the first planarization layer PAC1, the second planarization layer PAC2, and the third planarization layer PAC3 can be sequentially stacked in the red subpixel SP_R.

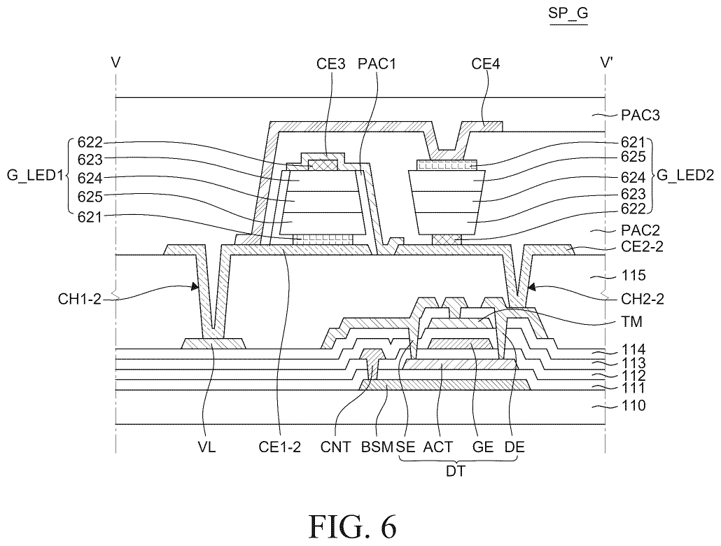

FIG. 6 is a cross-sectional view of the green subpixel among the subpixels of the display device taken along line V-V′ in FIG. 4 according to the embodiment of the present specification. In the green subpixel SP_G of the display device 100 according to the embodiment of the present specification, all the components disposed below the first-second connection electrode CE1-2 and the second-second connection electrode CE2-2 are identical to those of the red subpixel SP_R. Therefore, a repeated description thereof will be omitted.

With reference to FIG. 6, the first-second connection electrode CE1-2 and the second-second connection electrode CE2-2 can be disposed on the overcoating layer 115 in the green subpixel SP_G. In this case, the first-second connection electrode CE1-2 and the second-second connection electrode CE2-2 are substantially identical in configurations, arrangements, and functions to the first-first connection electrode CE1-1 and the second-first connection electrode CE2-1 of the red subpixel SP_R. Therefore, a repeated description thereof will be omitted.

The first green light-emitting element G_LED1 can be disposed on the first-second connection electrode CE1-2. Specifically, the first green light-emitting element G_LED1 can be disposed on one side portion of the first-second connection electrode CE1-2 and does not overlap the first-second contact hole CH1-2.

The first green light-emitting element G_LED1 and the second green light-emitting element G_LED2 can each include a first electrode 621, a first semiconductor layer 625, a second electrode 622, a second semiconductor layer 623, and a light-emitting layer 624.

The first electrode 621 of the first green light-emitting element G_LED1 can be disposed to face the first-second connection electrode CE1-2. The first electrode 621 can be electrically connected to the power line VL through the first-second connection electrode CE1-2. Therefore, the first electrode 621 can transmit the voltage, which is transmitted through the power line VL, to the first semiconductor layer 625. For example, the first electrode 621 can be an N-type electrode disposed to inject electrons into the light-emitting layer 624 through the first semiconductor layer 625. The first electrode 621 can be made of an electrically conductive material, for example, a transparent conductive material such as indium tin oxide (ITO) or indium zinc oxide (IZO) or an opaque conductive material such as titanium (Ti), gold (Au), silver (Ag), copper (Cu), or an alloy thereof. However, the present specification is not limited thereto.

The first semiconductor layer 625 can be disposed on the first electrode 621. For example, the first semiconductor layer 625 can be an N-type layer for supplying electrons to the light-emitting layer 624. In this case, the first semiconductor layer 625 can be formed by doping a gallium nitride (GaN) semiconductor layer, which is formed by growing a gallium nitride (GaN) layer, with N-type impurities such as silicon (Si), germanium (GE), or tin (Sn). However, the present specification is not limited thereto.

The light-emitting layer 624 can be disposed on the first semiconductor layer 625. The light-emitting layer 624 can emit light by receiving positive holes and electrons from the first semiconductor layer 625 and the second semiconductor layer 623 to be described below. The light-emitting layer 624 can be configured as a single layer or a multi-quantum well (MQW) structure. For example, the light-emitting layer 624 can be made of indium gallium nitride (InGaN), gallium nitride (GaN), or the like. However, the present specification is not limited thereto.

The second semiconductor layer 623 can be disposed on the light-emitting layer 624. For example, the second semiconductor layer 623 can be a P-type layer for injecting positive holes into the light-emitting layer 624. The second semiconductor layer 623 can be formed by doping a gallium nitride (GaN) semiconductor layer, which is formed by growing a gallium nitride (GaN) layer, with P-type impurities such as magnesium (Mg), zinc (Zn), and beryllium (Be). However, the present specification is not limited thereto.

The second electrode 622 can be disposed on the second semiconductor layer 623. For example, the second electrode 622 can be a P-type electrode for injecting positive holes into the light-emitting layer 624 through the second semiconductor layer 623. The second electrode 622 can be made of an electrically conductive material, for example, a transparent conductive material such as indium tin oxide (ITO) or indium zinc oxide (IZO) or an opaque conductive material such as titanium (Ti), gold (Au), silver (Ag), copper (Cu), or an alloy thereof. However, the present specification is not limited thereto. However, because the second electrode 622 is disposed above the light-emitting layer 624 in the first green light-emitting element G_LED1, the second electrode 622 can be made of an electrically conductive material having transparency so that the light emitted from the light-emitting layer 624 can propagate upward while passing through the second electrode 622. However, the present specification is not limited thereto.

The second green light-emitting element G_LED2 can be disposed on the second-second connection electrode CE2-2. In this case, the second green light-emitting element G_LED2 can be disposed in a state in which the first green light-emitting element G_LED1 is inverted. Specifically, the second green light-emitting element G_LED2 can be disposed such that the second electrode 622 faces the second-second connection electrode CE2-2. For example, the second green light-emitting element G_LED2 can have a shape in which the second electrode 622, the second semiconductor layer 623, the light-emitting layer 624, the first semiconductor layer 625, and the first electrode 621 are sequentially disposed on the second-second connection electrode CE2-2.

The first green light-emitting element G_LED1 and the second green light-emitting element G_LED2 can be substantially identical in specific configurations to each other, except for arrangement shapes. However, because the second green light-emitting element G_LED2 has a shape made by inverting the shape of the first green light-emitting element G_LED1, the first electrode 621 can be disposed at the upper side in comparison with the first green light-emitting element G_LED1 in which the first electrode 621 is disposed at the lower side. Therefore, in the second green light-emitting element G_LED2, the first electrode 621 can be made of an electrically conductive material having transparency so that the light emitted from the light-emitting layer 624 propagates upward while passing through the first electrode 621. For example, the first electrode 621 can be made of a material such as indium tin oxide (ITO) or indium zinc oxide (IZO). However, the present specification is not limited thereto.

As described above, the first green light-emitting element G_LED1 and the second green light-emitting element G_LED2 can each be a vertical type light-emitting element different in structure from the red light-emitting element R_LED. In addition, the first green light-emitting element G_LED1 and the second green light-emitting element G_LED2 can be smaller in size than the red light-emitting element R_LED.

Although not illustrated in the drawings, a bonding layer can be further disposed between the first-second connection electrode CE1-2 and the first green light-emitting element G_LED1 and between the second-second connection electrode CE2-2 and the second green light-emitting element G_LED2. In this case, the bonding layer can fix the first green light-emitting element G_LED1 and the second green light-emitting element G_LED2 onto the first-second connection electrode CE1-2 and the second-second connection electrode CE2-2. The bonding layer can include an electrically conductive material to electrically connect the first-second connection electrode CE1-2 and the first electrode 621 of the first green light-emitting element G_LED1 and electrically connect the second-second connection electrode CE2-2 and the second electrode 622 of the second green light-emitting element G_LED2. However, the present specification is not limited thereto.

In the green subpixel SP_G, the first planarization layer PAC1 can be disposed to surround a side surface of the first green light-emitting element G_LED1. Therefore, the first planarization layer PAC1 can fix and protect the first green light-emitting element G_LED1. In addition, the first planarization layer PAC1 can expose the second electrode 622 of the first green light-emitting element G_LED1. The first planarization layer PAC1 can be disposed to cover one end of the first-second connection electrode CE1-2. Further, one end of the first planarization layer PAC1 can be spaced apart from the second-second connection electrode CE2-2. The other end of the first planarization layer PAC1 does not overlap the first-second contact hole CH1-2. For example, the first planarization layer PAC1 can be made of benzocyclobutene or an acrylic-based organic material, for example. However, the present specification is not limited thereto.

A third connection electrode CE3 can be disposed on at least a part of the first planarization layer PAC1 and the second electrode 622 of the first green light-emitting element G_LED1. In this case, the third connection electrode CE3 can be disposed to cover the second electrode 622, extend along one side surface of the first planarization layer PAC1, and be connected to the second-second connection electrode CE2-2. Therefore, the third connection electrode CE3 can be disposed to cover one side surface of the first planarization layer PAC1. Therefore, the third connection electrode CE3 can electrically connect the second electrode 622 of the first green light-emitting element G_LED1 and the second-second connection electrode CE2-2. In addition, the third connection electrode CE3 can cover one end of the second-second connection electrode CE2-2 and be at least disposed on one side portion of the second-second connection electrode CE2-2. The third connection electrode CE3 can not extend to the other side surface of the first planarization layer PAC1.

The second planarization layer PAC2 can be disposed on the third connection electrode CE3. In the green subpixel SP_G, the second planarization layer PAC2 can be disposed to completely cover the first planarization layer PAC1 and the third connection electrode CE3 and protect the first green light-emitting element G_LED1 and the third connection electrode CE3. In addition, the second planarization layer PAC2 can be disposed to surround a side surface of the second green light-emitting element G_LED2 and cover at least a part of a top surface of the second green light-emitting element G_LED2. Therefore, the second planarization layer PAC2 can fix and cover the second green light-emitting element G_LED2. A top surface of the second planarization layer PAC2 can be disposed to be higher than a top surface of the first electrode 621 of the second green light-emitting element G_LED2. However, the second planarization layer PAC2 can expose at least a part of the first electrode 621 of the second green light-emitting element G_LED2. For example, the second planarization layer PAC2 can be made of benzocyclobutene or an acrylic-based organic material, for example. However, the present specification is not limited thereto.

A fourth connection electrode CE4 can be disposed on the second planarization layer PAC2. The fourth connection electrode CE4 can be disposed on the first electrode 621 of the second green light-emitting element G_LED2 exposed by the second planarization layer PAC2. The fourth connection electrode CE4 can extend along one side surface of the second planarization layer PAC2 and be connected to the first-second connection electrode CE1-2. Therefore, the first electrode 621 of the second green light-emitting element G_LED2 and the first-second connection electrode CE1-2 can be electrically connected by the fourth connection electrode CE4. As described above, the first green light-emitting element G_LED1 and the second green light-emitting element G_LED2 are connected in parallel to the green subpixel SP_G, such that the plurality of green light-emitting elements G_LED1 and G_LED2 can be disposed in one green subpixel SP_G. In addition, the fourth connection electrode CE4 can overlap the first green light-emitting element G_LED1, the first planarization layer PAC1, and the third connection electrode CE3 and overlap at least a part of the second green light-emitting element G_LED2.

The third planarization layer PAC3 can be disposed on the second planarization layer PAC2. The third planarization layer PAC3 can be disposed to cover all the second planarization layer PAC2, the fourth connection electrode CE4, the first-second connection electrode CE1-2, and the overcoating layer 115. Therefore, the third planarization layer PAC3 can protect all the components disposed below the third planarization layer PAC3. For example, the third planarization layer PAC3 can be made of benzocyclobutene or an acrylic-based organic material, for example. However, the present specification is not limited thereto.

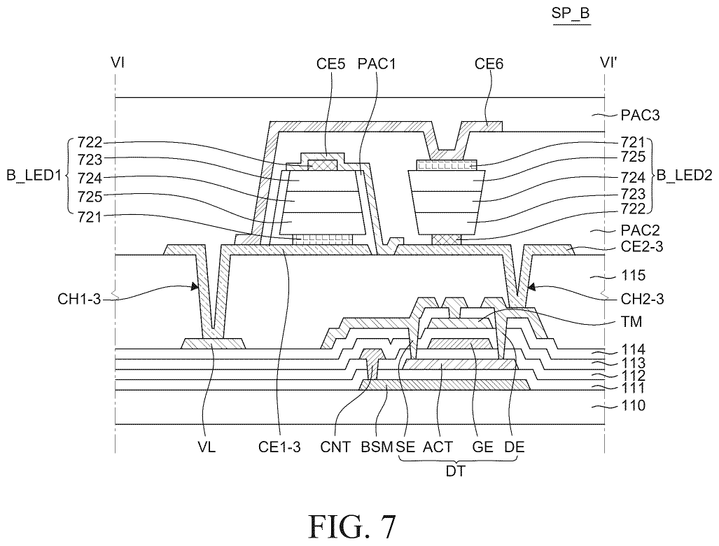

FIG. 7 is a cross-sectional view of the blue subpixel among the subpixels of the display device taken along line VI-VI′ in FIG. 4 according to the embodiment of the present specification. In the blue subpixel SP_B of the display device 100 according to the embodiment of the present specification, all the components disposed below the first-third connection electrode CE1-3 and the second-third connection electrode CE2-3 are identical to those of the red subpixel SP_R. Therefore, a repeated description thereof will be omitted.

With reference to FIG. 7, the first-third connection electrode CE1-3 and the second-third connection electrode CE2-3 can be disposed on the overcoating layer 115 in the blue subpixel SP_B. In this case, the first-third connection electrode CE1-3 and the second-third connection electrode CE2-3 are substantially identical in configurations, arrangements, and functions to the first-first connection electrode CE1-1 and the second-first connection electrode CE2-1 of the red subpixel SP_R. Therefore, a repeated description thereof will be omitted.

The first blue light-emitting element B_LED1 can be disposed on the first-third connection electrode CE1-3. Specifically, the first blue light-emitting element B_LED1 can be disposed on one side portion of the first-third connection electrode CE1-3 and does not overlap the first-third contact hole CH1-3.

The first blue light-emitting element B_LED1 and the second blue light-emitting element B_LED2 can each include a first electrode 721, a first semiconductor layer 725, a second electrode 722, a second semiconductor layer 723, and a light-emitting layer 724.

A first electrode 721 of the first blue light-emitting element B_LED1 can be disposed to face the first-third connection electrode CE1-3. The first electrode 721 can be electrically connected to the power line VL through the first-third connection electrode CE1-3. Therefore, the first electrode 721 can transmit the voltage, which is transmitted through the power line VL, to a first semiconductor layer 725. For example, the first electrode 721 can be an N-type electrode disposed to inject electrons into a light-emitting layer 724 through the first semiconductor layer 725. The first electrode 721 can be made of an electrically conductive material, for example, a transparent conductive material such as indium tin oxide (ITO) or indium zinc oxide (IZO) or an opaque conductive material such as titanium (Ti), gold (Au), silver (Ag), copper (Cu), or an alloy thereof. However, the present specification is not limited thereto.

The first semiconductor layer 725 can be disposed on the first electrode 721. For example, the first semiconductor layer 725 can be an N-type layer for supplying electrons to the light-emitting layer 724. In this case, the first semiconductor layer 725 can be formed by doping a gallium nitride (GaN) semiconductor layer, which is formed by growing a gallium nitride (GaN) layer, with N-type impurities such as silicon (Si), germanium (GE), or tin (Sn). However, the present specification is not limited thereto.

The light-emitting layer 724 can be disposed on the first semiconductor layer 725. The light-emitting layer 724 can emit light by receiving positive holes and electrons from the first semiconductor layer 725 and a second semiconductor layer 723 to be described below. The light-emitting layer 724 can be configured as a single layer or a multi-quantum well (MQW) structure. For example, the light-emitting layer 724 can be made of indium gallium nitride (InGaN), gallium nitride (GaN), or the like. However, the present specification is not limited thereto.

The second semiconductor layer 723 can be disposed on the light-emitting layer 724. For example, the second semiconductor layer 723 can be a P-type layer for injecting positive holes into the light-emitting layer 724. The second semiconductor layer 723 can be formed by doping a gallium nitride (GaN) semiconductor layer, which is formed by growing a gallium nitride (GaN) layer, with P-type impurities such as magnesium (Mg), zinc (Zn), and beryllium (Be). However, the present specification is not limited thereto.

A second electrode 722 can be disposed on the second semiconductor layer 723. For example, the second electrode 722 can be a P-type electrode for injecting positive holes into the light-emitting layer 724 through the second semiconductor layer 723. The second electrode 722 can be made of an electrically conductive material, for example, a transparent conductive material such as indium tin oxide (ITO) or indium zinc oxide (IZO) or an opaque conductive material such as titanium (Ti), gold (Au), silver (Ag), copper (Cu), or an alloy thereof. However, the present specification is not limited thereto. However, because the second electrode 722 is disposed above the light-emitting layer 724 in the first blue light-emitting element B_LED1, the second electrode 722 can be made of an electrically conductive material having transparency so that the light emitted from the light-emitting layer 724 can propagate upward while passing through the second electrode 722. However, the present specification is not limited thereto.

The second blue light-emitting element B_LED2 can be disposed on the second-third connection electrode CE2-3. In this case, the second blue light-emitting element B_LED2 can be disposed in a state in which the first blue light-emitting element B_LED1 is inverted. Specifically, the second blue light-emitting element B_LED2 can be disposed such that the second electrode 722 faces the second-third connection electrode CE2-3. For example, the second blue light-emitting element B_LED2 can have a shape in which the second electrode 722, the second semiconductor layer 723, the light-emitting layer 724, the first semiconductor layer 725, and the first electrode 721 are sequentially disposed on the second-third connection electrode CE2-3. The first blue light-emitting element B_LED1 and the second blue light-emitting element B_LED2 can be substantially identical in specific configuration to each other, except for arrangement shapes. However, because the second blue light-emitting element B_LED2 has a shape made by inverting the shape of the first blue light-emitting element B_LED1, the first electrode 721 can be disposed at the upper side in comparison with the first blue light-emitting element B_LED1 in which the first electrode 721 is disposed at the lower side. Therefore, in the second blue light-emitting element B_LED2, the first electrode 721 can be made of an electrically conductive material having transparency so that the light emitted from the light-emitting layer 724 propagates upward while passing through the first electrode 721. For example, the first electrode 721 can be made of a material such as indium tin oxide (ITO) or indium zinc oxide (IZO). However, the present specification is not limited thereto.

As described above, the first blue light-emitting element B_LED1 and the second blue light-emitting element B_LED2 can each be a vertical type light-emitting element different in structure from the red light-emitting element R_LED. In contrast, the plurality of blue light-emitting elements B_LED1 and B_LED2 disposed in the blue subpixel SP_B can be identical in structures to the plurality of green light-emitting elements G_LED1 and G_LED2 disposed in the green subpixel SP_G.

In addition, the first blue light-emitting element B_LED1 and the second blue light-emitting element B_LED2 can be smaller in size than the red light-emitting element R_LED. Meanwhile, the plurality of blue light-emitting elements B_LED1 and B_LED2 disposed in the blue subpixel SP_B can be identical in sizes to the plurality of green light-emitting elements G_LED1 and G_LED2 disposed in the green subpixel SP_G. However, the present specification is not limited thereto.

Although not illustrated in the drawings, a bonding layer can be further disposed between the first-third connection electrode CE1-3 and the first blue light-emitting element B_LED1 and between the second-third connection electrode CE2-3 and the second blue light-emitting element B_LED2. In this case, the bonding layer can fix the first blue light-emitting element B_LED1 and the second blue light-emitting element B_LED2 onto the first-third connection electrode CE1-3 and the second-third connection electrode CE2-3. The bonding layer can include an electrically conductive material to electrically connect the first-third connection electrode CE1-3 and the first electrode 721 of the first blue light-emitting element B_LED1 and electrically connect the second-third connection electrode CE2-3 and the second electrode 722 of the second blue light-emitting element B_LED2. However, the present specification is not limited thereto.

In the blue subpixel SP_B, the first planarization layer PAC1 can be disposed to surround a side surface of the first blue light-emitting element B_LED1. Therefore, the first planarization layer PAC1 can fix and protect the first blue light-emitting element B_LED1. In addition, the first planarization layer PAC1 can expose the second electrode 722 of the first blue light-emitting element B_LED1. The first planarization layer PAC1 can be disposed to cover one end of the first-third connection electrode CE1-3. Further, one end of the first planarization layer PAC1 can be spaced apart from the second-third connection electrode CE2-3. The other end of the first planarization layer PAC1 does not overlap the first-third contact hole CH1-3. For example, the first planarization layer PAC1 can be made of benzocyclobutene or an acrylic-based organic material, for example. However, the present specification is not limited thereto.

A fifth connection electrode CE5 can be disposed on at least a part of the first planarization layer PAC1 and the second electrode 722 of the first blue light-emitting element B_LED1. In this case, the fifth connection electrode CE5 can be disposed to cover the second electrode 722, extend along one side surface of the first planarization layer PAC1, and be connected to the second-third connection electrode CE2-3. Therefore, the fifth connection electrode CE5 can be disposed to cover one side surface of the first planarization layer PAC1. Therefore, the fifth connection electrode CE5 can electrically connect the second electrode 722 of the first blue light-emitting element B_LED1 and the second-third connection electrode CE2-3. In addition, the fifth connection electrode CE5 can cover one end of the second-third connection electrode CE2-3 and be at least disposed on one side portion of the second-third connection electrode CE2-3. The fifth connection electrode CE5 can not extend to the other side surface of the first planarization layer PAC1.

The second planarization layer PAC2 can be disposed on the fifth connection electrode CE5. In the blue subpixel SP_B, the second planarization layer PAC2 can be disposed to completely cover the first planarization layer PAC1 and the fifth connection electrode CE5 and protect the first blue light-emitting element B_LED1 and the fifth connection electrode CE5. In addition, the second planarization layer PAC2 can be disposed to surround a side surface of the second blue light-emitting element B_LED2 and cover at least a part of a top surface of the second blue light-emitting element B_LED2. Therefore, the second planarization layer PAC2 can fix and protect the second blue light-emitting element B_LED2. A top surface of the second planarization layer PAC2 can be disposed to be higher than a top surface of the first electrode 721 of the second blue light-emitting element B_LED2. However, the second planarization layer PAC2 can expose at least a part of the first electrode 721 of the second blue light-emitting element B_LED2. For example, the second planarization layer PAC2 can be made of benzocyclobutene or an acrylic-based organic material, for example. However, the present specification is not limited thereto.

A sixth connection electrode CE6 can be disposed on the second planarization layer PAC2. The sixth connection electrode CE6 can be disposed on the first electrode 721 of the second blue light-emitting element B_LED2 exposed by the second planarization layer PAC2. The sixth connection electrode CE6 can extend along one side surface of the second planarization layer PAC2 and be connected to the first-third connection electrode CE1-3. Therefore, the first electrode 721 of the second blue light-emitting element B_LED2 and the first-third connection electrode CE1-3 can be electrically connected by the sixth connection electrode CE6. As described above, the first blue light-emitting element B_LED1 and the second blue light-emitting element B_LED2 are connected in parallel to the blue subpixel SP_B, such that the plurality of blue light-emitting elements B_LED1 and B_LED2 can be disposed in one blue subpixel SP_B. In addition, the sixth connection electrode CE6 can overlap the first blue light-emitting element B_LED1, the first planarization layer PAC1, and the fifth connection electrode CE5 and overlap at least a part of the second blue light-emitting element G_LED2. The third planarization layer PAC3 can be disposed on the second planarization layer PAC2. The third planarization layer PAC3 can be disposed to cover all the second planarization layer PAC2, the sixth connection electrode CE6, the first-third connection electrode CE1-3, and the overcoating layer 115. Therefore, the third planarization layer PAC3 can protect all the components disposed below the third planarization layer PAC3. For example, the third planarization layer PAC3 can be made of benzocyclobutene or an acrylic-based organic material, for example. However, the present specification is not limited thereto.

The light-emitting element configured by a light emitting diode (LED) refers to a semiconductor light-emitting element using the property of emitting light when an electric current is applied to a semiconductor. The light-emitting element can be made of a compound semiconductor such as gallium arsenide (GaAs) or gallium nitride (GaN). Because of the nature of the inorganic material, a high electric current can be injected into the compound semiconductor, such that the compound semiconductor can implement high luminance and implement the display device with low power consumption. Therefore, the compound semiconductor can be widely used for various display devices. Recently, technologies for manufacturing high-resolution display devices by using micro-sized LEDs have been developed. The micro-LED has an excellent effect of displaying electric current. When the electric current is injected, the electric current is effectively injected into the active layer in the LED, such that light output per unit area and current density can be improved in comparison with a large-area LED.

However, in the case of the micro-LED, a ratio of an exposed sidewall area to a light-emitting area increases in comparison with the large-area LED in the related art. In this case, there occurs a problem in that the occurrence of non-radiative recombination, in which electron-hole pairs cannot be normally coupled because of surface defect states present on the sidewall, rapidly increases, and a leakage current is generated. This problem causes an efficiency droop in which external quantum efficiency (EQE) deteriorates as a current density increases.

Meanwhile, the micro-LEDs can be configured as various types such as a lateral type micro LED, a vertical type micro LED, or a flip-chip type micro LED. In the case of the lateral type micro LED and the flip-chip type micro LED, the n-type electrode and the p-type electrode can be formed on the same plane. In contrast, in the case of the vertical type micro LED with a vertical structure, the n-type electrode and the p-type electrode can be disposed in the vertical direction, such that the vertical micro LED can be smaller in size than the lateral type micro LED and the flip-chip type micro LED. Therefore, when the vertical type micro LED, which occupies a small area, is disposed in the same area, it is possible to implement the display device with higher resolution.

However, as described above, a ratio of the exposed sidewall area to the light-emitting area increases as the size of the micro-LED decreases. Therefore, there is a problem in that the probability of the occurrence of non-radiative recombination and leakage current occurring on the sidewall also increases. In particular, the above-mentioned problem occurs more frequently in the red light-emitting element than in the green light-emitting element and the blue light-emitting element because of a difference in components used for the respective micro-LEDs. Specifically, the semiconductor layer of the red light-emitting element mainly includes gallium arsenide (GaAs), and the green light-emitting element and the blue light-emitting element mainly include gallium nitride (GaN). Because gallium arsenide (GaAs) has a larger diffusion constant than gallium nitride (GaN), the probability of the occurrence of non-radiative recombination and leakage current is higher in the red light-emitting element, which includes gallium arsenide (GaAs) as a main component, than the green light-emitting element or the blue light-emitting element that includes gallium nitride (GaN) as a main component. Therefore, in the high-resolution display device using the vertical type micro LED, there is a problem in that the deterioration in efficiency of the red light-emitting element than that of the green light-emitting element or the blue light-emitting element.

Therefore, in the display device 100 according to the embodiment of the present specification, the red light-emitting element R_LED, which is different in structure from the green light-emitting element G_LED and the blue light-emitting element B_LED, is disposed in the red subpixel SP_R. For example, the flip-chip or lateral type red light-emitting element R_LED can be disposed in the red subpixel SP_R, and the vertical type green light-emitting element G_LED and the blue light-emitting element B_LED can be disposed in the green subpixel SP_G and the blue subpixel SP_B. As described above, the flip-chip or lateral type red light-emitting element R_LED is disposed in the red subpixel SP_R, instead of the vertical type red light-emitting element R_LED in which the probability of the occurrence of non-radiative recombination and leakage current is high. Therefore, it is possible to suppress a deterioration in luminous efficiency of the red subpixel SP_R.

Further, the green light-emitting elements G_LED1 and G_LED2 and the blue light-emitting elements B_LED1 and B_LED2, which are vertical types with excellent luminous efficiency, are disposed in the green subpixel SP_G and the blue subpixel SP_B, which can implement the display device 100 with high resolution.

Meanwhile, in the display device 100 according to the embodiment of the present specification, the green light-emitting element G_LED and the blue light-emitting element B_LED, which have vertical type structures, can be disposed in the green subpixel SP_G and the blue subpixel SP_B. In this case, the plurality of green light-emitting elements G_LED and the plurality of blue light-emitting elements B_LED are disposed in each of the subpixels. Because the green light-emitting element G_LED and the blue light-emitting element B_LED, which have the vertical type structures, are smaller in size than the red light-emitting element R_LED, the plurality of light-emitting elements can be disposed in one subpixel. In addition, as the size of the light-emitting element decreases, the size of the electrode connected to the light-emitting element can also decrease. As described above, as the light-emitting element and the electrode connected to the light-emitting element decrease in size, such that an area in which the green subpixel SP_G and the blue subpixel SP_B are disposed can decrease. Therefore, a larger number of subpixels can be disposed in the same area of the display device, such that the display device with higher resolution can be implemented.

In addition, in the display device 100 according to the embodiment of the present specification, the plurality of green light-emitting elements G_LED1 and G_LED2 and the plurality of blue light-emitting elements B_LED1 and B_LED2 are respectively connected in parallel to the green subpixel SP_G and the blue subpixel SP_B. The green light-emitting elements G_LED1 and G_LED2 and the blue light-emitting elements B_LED1 and B_LED2, which are connected in parallel as described above, can be operated by the single driving transistor DT. Therefore, even though any one light-emitting element is defective among the light-emitting elements disposed in the green subpixel SP_G and the blue subpixel SP_B, another light-emitting element, which is connected in parallel, can be substituted for the defective light-emitting element. Therefore, it is possible to minimize a deterioration in image quality caused by the occurrence of defect in the green subpixel SP_G and the blue subpixel SP_B.

The exemplary embodiments of the present specification can also be described as follows:

According to as aspect of the present specification, a display device comprises a substrate on which a plurality of subpixels comprising a red subpixel, a green subpixel, and a blue subpixel are defined, a red light-emitting element disposed in the red subpixel, a plurality of green light-emitting elements disposed in the green subpixel and comprising a first green light-emitting element and a second green light-emitting element connected in parallel to the first green light-emitting element, and a plurality of blue light-emitting elements disposed in the blue subpixel and comprising a first blue light-emitting element and a second blue light-emitting element connected in parallel to the first blue light-emitting element, wherein the red light-emitting element is different in structure from the plurality of green light-emitting elements and the plurality of blue light-emitting elements and the plurality of green light-emitting elements and the plurality of blue light-emitting elements are identical in structure.

The red light-emitting element can be larger in size than the plurality of green light-emitting elements and the plurality of blue light-emitting elements.

The red light-emitting element can be a flip-chip type light-emitting element, and the plurality of green light-emitting elements and the plurality of blue light-emitting elements can be vertical type light-emitting elements.

The display device can further comprise a transistor disposed in each of the plurality of subpixels on the substrate, a power line disposed in the plurality of subpixels on the substrate,
a plurality of first connection electrodes disposed on the power line in each of the plurality of subpixels and electrically connected to the power line, and a plurality of second connection electrodes disposed on the transistor in each of the plurality of subpixels and electrically connected to the transistor, wherein the plurality of first connection electrodes can comprise a first-first connection electrode disposed in the red subpixel, a first-second connection electrode disposed in the green subpixel and a first-third connection electrode disposed in the blue subpixel, wherein the plurality of second connection electrodes can comprise a second-first connection electrode disposed in the red subpixel, a second-second connection electrode disposed in the green subpixel, and a second-third connection electrode disposed in the blue subpixel, wherein the red light-emitting element can be disposed on the first-first connection electrode and the second-first connection electrode, wherein the first green light-emitting element can be disposed on the first-second connection electrode, wherein the second green light-emitting element can be disposed on the second-second connection electrode, wherein the first blue light-emitting element can be disposed on the first-third connection electrode, and wherein the second blue light-emitting element can be disposed on the second-third connection electrode.

A first electrode of the red light-emitting element can be disposed to face the first-first connection electrode, and a second electrode of the red light-emitting element can be disposed to face the second-first connection electrode.

A first electrode of the first green light-emitting element can be disposed to face the first-second connection electrode, and a second electrode of the second green light-emitting element can be disposed to face the second-second connection electrode.

The display device can further comprise a first planarization layer disposed to surround a side surface of the first green light-emitting element and configured to expose a second electrode of the first green light-emitting element, a third connection electrode disposed on the first planarization layer and configured to connect the second-second connection electrode and the second electrode of the first green light-emitting element, a second planarization layer disposed to cover the first green light-emitting element, the first planarization layer, the third connection electrode, and the second green light-emitting element, and configured to expose a first electrode of the second green light-emitting element and a fourth connection electrode disposed on the second planarization layer and configured to connect the first-second connection electrode and the first electrode of the second green light-emitting element.

The fourth connection electrode can overlap the first green light-emitting element, the first planarization layer, and the third connection electrode.

A first electrode of the first blue light-emitting element can be disposed to face the first-third connection electrode, and a second electrode of the second blue light-emitting element can be disposed to face the second-third connection electrode.

The display device can further comprise a first planarization layer disposed to cover the first blue light-emitting element and configured to expose a second electrode of the first blue light-emitting element, a fifth connection electrode disposed on the first planarization layer and configured to connect the second-third connection electrode and the second electrode of the first blue light-emitting element, a second planarization layer disposed to cover the first blue light-emitting element, the first planarization layer, the fifth connection electrode, and the second blue light-emitting element, and configured to expose a first electrode of the second blue light-emitting element, and a sixth connection electrode disposed on the second planarization layer and configured to connect the first-third connection electrode and the first electrode of the second blue light-emitting element.

The sixth connection electrode can overlap the first blue light-emitting element, the first planarization layer, and the fifth connection electrode.

An area of a top surface of the first-first connection electrode can be larger than those of the first-second connection electrode and the first-third connection electrode, and an area of a top surface of the second-first connection electrode can be larger than those of the second-second connection electrode and the second-third connection electrode.

Although the exemplary embodiments of the present specification have been described in detail with reference to the accompanying drawings, the present specification is not limited thereto and can be embodied in many different forms without departing from the technical concept of the present specification. Therefore, the exemplary embodiments of the present specification are provided for illustrative purposes only but not intended to limit the technical concept of the present specification. The scope of the technical concept of the present specification is not limited thereto. Therefore, it should be understood that the above-described exemplary embodiments are illustrative in all aspects and do not limit the present specification. All the technical concepts in the equivalent scope of the present specification should be construed as falling within the scope of the present specification.

What is claimed is:

1. A display device comprising:
a substrate on which a plurality of subpixels comprising a red subpixel, a green subpixel, and a blue subpixel are defined;
a red light-emitting element in the red subpixel;
a plurality of green light-emitting elements in the green subpixel, the plurality of green light-emitting elements comprising a first green light-emitting element and a second green light-emitting element that is connected in parallel to the first green light-emitting element; and
a plurality of blue light-emitting elements in the blue subpixel, the plurality of blue light-emitting elements comprising a first blue light-emitting element and a second blue light-emitting element that is connected in parallel to the first blue light-emitting element,
wherein the red light-emitting element is different in structure from the plurality of green light-emitting elements and the plurality of blue light-emitting elements and the plurality of green light-emitting elements and the plurality of blue light-emitting elements are identical in structure.

2. The display device of claim 1, wherein the red light-emitting element is larger in size than the plurality of green light-emitting elements and the plurality of blue light-emitting elements.

3. The display device of claim 1, wherein the red light-emitting element is a flip-chip type light-emitting element, and the plurality of green light-emitting elements and the plurality of blue light-emitting elements are vertical type light-emitting elements.

4. The display device of claim 1, further comprising:
a transistor in each of the plurality of subpixels on the substrate;
a power line in the plurality of subpixels on the substrate;
a plurality of first connection electrodes on the power line in each of the plurality of subpixels, the plurality of first connection electrodes electrically connected to the power line; and
a plurality of second connection electrodes on the transistor in each of the plurality of subpixels, the plurality of second connection electrodes electrically connected to the transistor,
wherein the plurality of first connection electrodes comprises:
a first-first connection electrode in the red subpixel;
a first-second connection electrode in the green subpixel; and
a first-third connection electrode in the blue subpixel,
wherein the plurality of second connection electrodes comprises:
a second-first connection electrode in the red subpixel;
a second-second connection electrode in the green subpixel; and
a second-third connection electrode in the blue subpixel,
wherein the red light-emitting element is on the first-first connection electrode and the second-first connection electrode,
wherein the first green light-emitting element is on the first-second connection electrode,
wherein the second green light-emitting element is on the second-second connection electrode,
wherein the first blue light-emitting element is on the first-third connection electrode, and
wherein the second blue light-emitting element is on the second-third connection electrode.

5. The display device of claim 4, wherein a first electrode of the red light-emitting element faces the first-first connection electrode, and a second electrode of the red light-emitting element faces the second-first connection electrode.

6. The display device of claim 4, wherein a first electrode of the first green light-emitting element faces the first-second connection electrode, and a second electrode of the second green light-emitting element faces the second-second connection electrode.

7. The display device of claim 6, further comprising:
a first planarization layer that surrounds a side surface of the first green light-emitting element and exposes a second electrode of the first green light-emitting element;
a third connection electrode on the first planarization layer and connects the second-second connection electrode and the second electrode of the first green light-emitting element;
a second planarization layer that covers the first green light-emitting element, the first planarization layer, the third connection electrode, and the second green light-emitting element, and exposes a first electrode of the second green light-emitting element; and
a fourth connection electrode on the second planarization layer and connects the first-second connection electrode and the first electrode of the second green light-emitting element.

8. The display device of claim 7, wherein the fourth connection electrode overlaps the first green light-emitting element, the first planarization layer, and the third connection electrode.

9. The display device of claim 4, wherein a first electrode of the first blue light-emitting element faces the first-third connection electrode and a second electrode of the second blue light-emitting element faces the second-third connection electrode.

10. The display device of claim 9, further comprising:
a first planarization layer that covers the first blue light-emitting element and exposes a second electrode of the first blue light-emitting element;
a fifth connection electrode on the first planarization layer and connects the second-third connection electrode and the second electrode of the first blue light-emitting element;
a second planarization layer that covers the first blue light-emitting element, the first planarization layer, the fifth connection electrode, and the second blue light-emitting element, and exposes a first electrode of the second blue light-emitting element; and
a sixth connection electrode on the second planarization layer and connects the first-third connection electrode and the first electrode of the second blue light-emitting element.

11. The display device of claim 10, wherein the sixth connection electrode overlaps the first blue light-emitting element, the first planarization layer, and the fifth connection electrode.

12. The display device of claim 4, wherein an area of a top surface of the first-first connection electrode is larger than respective ones of the first-second connection electrode and the first-third connection electrode, and an area of a top surface of the second-first connection electrode is larger than respective ones of the second-second connection electrode and the second-third connection electrode.
